(19) United States
(12) Patent Application Publication
(10) Pub. No.: US 2026/0321948 A1
(43) Pub. Date: Oct. 15, 2026

(54) HIGH-FREQUENCY SIGNAL TRANSMISSION LINE AND ELECTRONIC DEVICE

(71) Applicant: Murata Manufacturing Co., Ltd., Nagaokakyo-shi (JP)

(72) Inventors: Nobuo IKEMOTO, Nagaokakyo-shi (JP); Yasuhiro OUCHI, Nagaokakyo-shi (JP); Masanori OKAMOTO, Nagaokakyo-shi (JP)

(21) Appl. No.: 19/697,768

(22) Filed: Jun. 4, 2026

Related U.S. Application Data
(63) Continuation of application No. PCT/JP2024/039620, filed on Nov. 7, 2024.

(30) Foreign Application Priority Data
Dec. 6, 2023 (JP) 2023-206248

(51) Int. Cl. H01P 3/08; H05K 1/02; H05K 1/11

(52) U.S. Cl. CPC H01P 3/087; H05K 1/024; H05K 1/0242; H05K 1/115; H05K 2201/0129; H05K 2201/0141; H05K 2201/015; H05K 2201/0154; H05K 2201/0158; H05K 2201/0195; H05K 2201/0394

(57) ABSTRACT

A high-frequency signal transmission line includes a resin stacked portion including a first resin layer and a second resin layer, a signal conductor pattern on the first resin layer, and a ground conductor layer on the first resin layer. A first opening is located in the first resin layer along the signal conductor pattern in the resin stacked portion, and a second opening overlapping the first opening is located in a second resin layer, so that a hollow portion is provided in the resin stacked portion at the first opening or the second opening, an opening width of the second opening is smaller than an opening width of the first opening, an opening width of the second opening is greater than a line width of the signal conductor pattern, and the second resin layer has a lower dielectric constant or a lower dielectric loss tangent than the first resin layer.

### CROSS REFERENCE TO RELATED APPLICATIONS

This application claims the benefit of priority to Japanese Patent Application No. 2023-206248 filed on Dec. 6, 2023 and is a Continuation Application of PCT Application No. PCT/JP 2024/039620 filed on Nov. 7, 2024. The entire contents of each application are hereby incorporated herein by reference.

### BACKGROUND OF THE INVENTION

### 1. Field of the Invention

The present invention relates to a high-frequency signal transmission line and an electronic device including the same.

### 2. Description of the Related Art

International Publication WO 2022/113591 A discloses a transmission line having a suspended structure in which a signal line is formed in a resin layer and hollow portions are formed above and below the signal line. In addition, the side surface of the adhesive layer in contact with the hollow portion is configured to have a concave shape.

### SUMMARY OF THE INVENTION

In the high-frequency signal transmission line described in International Publication WO 2022/113591 A, since the sizes of the through hole (hollow portion) of the adhesive layer and the through hole (hollow portion) of the base material layer are the same, when stacking deviation between the adhesive layer and the base material layer occurs, a portion that does not partially overlap occurs, so that the strength and electrical characteristics of the high-frequency signal transmission line are deteriorated. In addition, it is difficult to perform processing on the high-frequency signal transmission lines having the same dimensions.

Therefore, example embodiments of the present invention provide high-frequency signal transmission lines that each maintain high strength of a resin stacked portion and a hollow portion and has stable electrical characteristics, and electronic devices including the high-frequency signal transmission lines.

A high-frequency signal transmission line according to an example embodiment of the present disclosure includes a resin stacked portion in which a single or a plurality of first resin layers and a single or a plurality of second resin layers are stacked, a signal conductor pattern in contact with at least a single first resin layer of the first resin layers, and a ground conductor layer in contact with at least a single first resin layer of the first resin layers, in which a first opening is located in at least a single first resin layer among the first resin layers at a position along the signal conductor pattern in the resin stacked portion, and a second opening overlapping the first opening is located in at least a single second resin layer among the second resin layers, so that a hollow portion is provided in the resin stacked portion at the first opening or the second opening, an opening width of the second opening is smaller than an opening width of the first opening, an opening width of the second opening is greater than a line width of the signal conductor pattern, and the second resin layer has a lower dielectric constant or a lower dielectric loss tangent than the first resin layer.

According to example embodiments of the present invention, even when there is stacking deviation between the adhesive layer and the base material layer, a decrease in the adhesion area between the adhesive layer and the base material layer is reduced or prevented, and a decrease in the bonding strength between the adhesive layer and the base material layer can be prevented. Therefore, it is possible to obtain high-frequency signal transmission lines that each maintain high strength of a resin stacked portion and a hollow portion and has stable electrical characteristics, and electronic devices including the high-frequency signal transmission lines.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a plan view of a high-frequency signal transmission line 101 according to a first example embodiment of the present invention.

FIG. 2 is a longitudinal cross-sectional view (upper portion) taken along a one-dot chain line A-A in FIG. 2, and is a longitudinal cross-sectional view (lower portion) taken along a one-dot chain line B-B in FIG. 1.

FIG. 3 is an exploded plan view of layers of the high-frequency signal transmission line 101 illustrated in FIG. 1 before pressurization and heat-pressing at the time of manufacturing.

FIG. 4 is a cross-sectional view illustrating a stacking deviation state of each resin layer in the high-frequency signal transmission line of the first example embodiment of the present invention.

FIG. 5 is a cross-sectional view of a high-frequency signal transmission line 102A according to a second example embodiment of the present invention.

FIG. 6 is a cross-sectional view of another high-frequency signal transmission line 102B according to the second example embodiment of the present invention.

FIG. 7 is a cross-sectional view of a high-frequency signal transmission line 103 according to a third example embodiment of the present invention.

FIG. 8 is a cross-sectional view of a high-frequency signal transmission line 104 according to a fourth example embodiment of the present invention.

FIG. 9 is a cross-sectional view of a high-frequency signal transmission line 105 according to a fifth example embodiment of the present invention.

FIG. 10 is a longitudinal cross-sectional view of a high-frequency signal transmission line 106 according to a sixth example embodiment of the present invention.

FIG. 11 is a longitudinal cross-sectional view of a high-frequency signal transmission line 107 according to a seventh example embodiment of the present invention.

FIG. 12 is a cross-sectional view (upper portion) of a high-frequency signal transmission line 108A according to an eighth example embodiment of the present invention. The lower portion of FIG. 12 is a cross-sectional view of a high-frequency signal transmission line 108B according to the eighth example embodiment of the present invention.

FIG. 13 is a longitudinal cross-sectional view (upper portion) of a high-frequency signal transmission line 109A according to a ninth example embodiment of the present invention. The lower portion of FIG. 13 is a longitudinal cross-sectional view of a high-frequency signal transmission line 109B according to the ninth example embodiment of the present invention.

FIG. 14 is a plan view of high-frequency signal transmission lines 110A, 110B, and 110C according to a tenth example embodiment of the present invention.

FIG. 15 is a cross-sectional view (upper portion) of a high-frequency signal transmission line 111 according to an eleventh example embodiment of the present invention. The lower portion of FIG. 15 is a cross-sectional view of the high-frequency signal transmission line 110 illustrating a state of the electric field distribution by the lines of electric force.

FIG. 16 is a longitudinal cross-sectional view of a high-frequency signal transmission line 112 according to a twelfth example embodiment of the present invention.

### DETAILED DESCRIPTION OF THE EXAMPLE EMBODIMENTS

Hereinafter, a plurality of example embodiments of the present invention will be shown with some specific examples with reference to the drawings. In each figure, the same components, elements, features, portions, etc., are designated by the same reference signs. In consideration of the description of the main points or ease of understanding, the example embodiments are divided into a plurality of example embodiments for convenience of description, but partial replacement or combination of configurations shown in different example embodiments is possible. In second and subsequent example embodiments, description of matters common to a first example embodiment will be omitted, and only different points will be described. In particular, similar functions and effects obtained by the same configuration will not be sequentially described for each example embodiment.

In the first example embodiment of the present invention, an example of a strip-line-type high-frequency signal transmission line will be described.

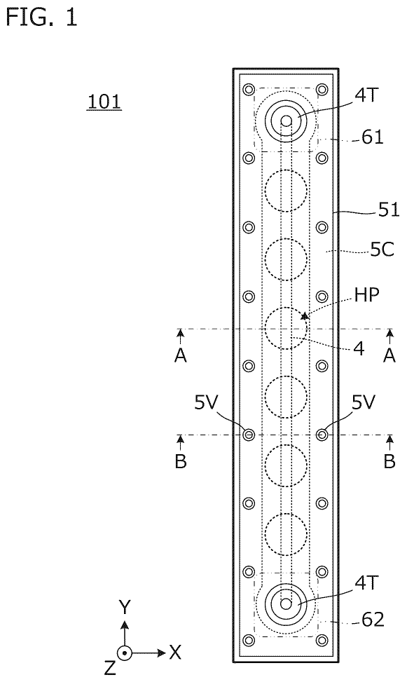

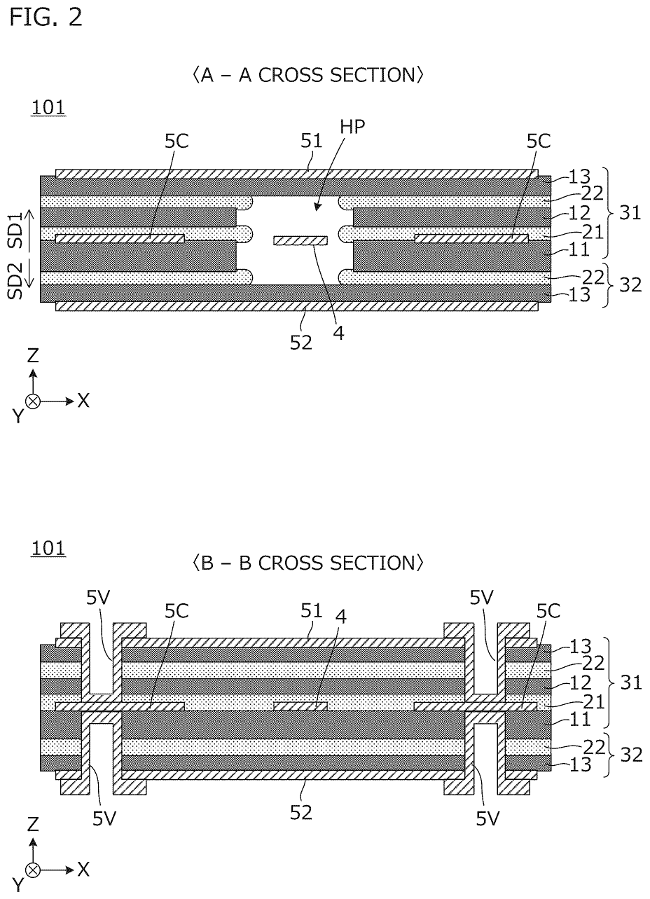

FIG. 1 is a plan view of a high-frequency signal transmission line 101 according to the first example embodiment of the present invention. The upper portion of FIG. 2 is a longitudinal cross-sectional view taken along a one-dot chain line A-A in FIG. 2, and the lower portion of FIG. 2 is a longitudinal cross-sectional view taken along a one-dot chain line B-B in FIG. 1. In the cross-sectional view, a line appearing in the cross section (appearing by cutting) is drawn, and illustration of a line existing behind the cross section is omitted. This also applies to each example embodiment described below.

Although a single high-frequency signal transmission line 101 is illustrated in FIG. 1, a large number of high-frequency signal transmission lines continuous in the plane direction are manufactured until the final process at the time of manufacturing, and are separated into the high-frequency signal transmission lines in the final process. This also applies to each example embodiment described below.

The high-frequency signal transmission line 101 includes an upper resin stacked portion 31, a lower resin stacked portion 32, a signal conductor pattern 4, a first ground conductor layer 51, a second ground conductor layer 52, and a ground conductor pattern 5C. The ground conductor pattern 5C is electrically connected to the first ground conductor layer 51 and the second ground conductor layer 52 via the interlayer connection conductor 5V.

The upper resin stacked portion 31 is a portion where the first resin layers 11, 12, and 13 and the second resin layers 21 and 22 are stacked. The lower resin stacked portion 32 is a portion where the first resin layer 13 and the second resin layer 22 are stacked. The signal conductor pattern 4 and the ground conductor pattern 5C are on the upper surface of the first resin layer 11. A first ground conductor layer 51 is stacked on the upper surface of the upper first resin layer 13. A second ground conductor layer 52 is stacked on the lower surface of the lower first resin layer 13. That is, the signal conductor pattern 4 is disposed between the first ground conductor layer 51 and the second ground conductor layer 52 with the resin stacked portions 31 and 32 interposed therebetween.

As illustrated in the upper portion of FIG. 2, the second resin layer 22 located at the uppermost portion of the hollow portion HP includes an opening continuous with the opening of the first resin layer 12. Similarly, the second resin layer 22 located at the lowermost portion of the hollow portion HP includes an opening continuous with the opening of the first resin layer 11. The hollow portion HP overlaps with the signal conductor pattern 4 when viewed in a stacking direction. A portion of the hollow portion HP is located between the signal conductor pattern 4 and the first ground conductor layer 51. In addition, a different portion of the hollow portion HP is located between the signal conductor pattern 4 and the second ground conductor layer 52.

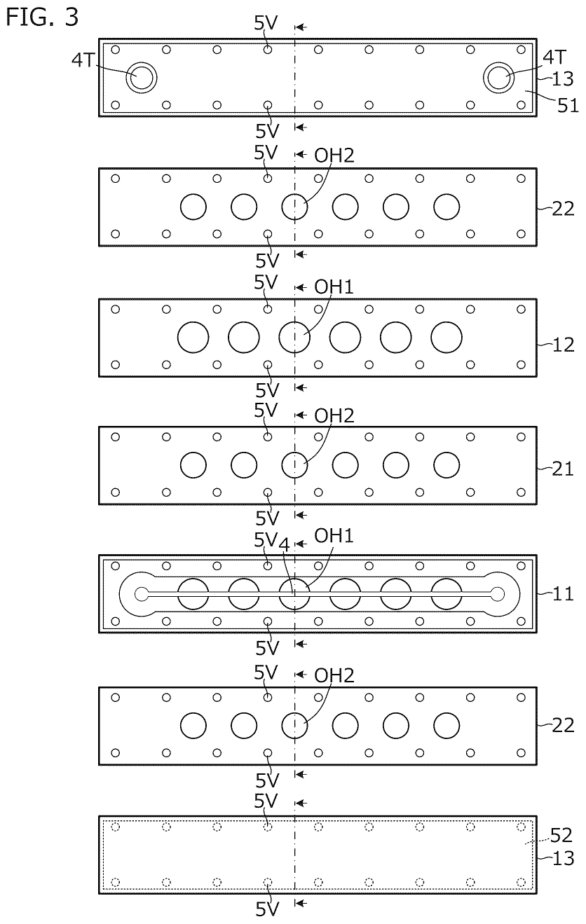

FIG. 3 is an exploded plan view of layers of the high-frequency signal transmission line 101 illustrated in FIG. 1 before pressurization and heat-pressing at the time of manufacturing.

A first opening OH1 is located in the first resin layers 11 and 12. A second opening OH2 is located in the second resin layers 21 and 22. The second opening OH2 is also located in the lower second resin layer 22. When expressed by the shape in the drawing, these openings are circular as viewed in the stacking direction of the first resin layers 11, 12, and 13 and the second resin layers 21 and 22.

As described above, the circular first opening OH1 is located in the first resin layers 11, 12, and 13, and the circular second opening OH2 is located in the upper second resin layers 21 and 22 and the lower second resin layer 22, so that the hollow portion HP is provided at these openings.

The opening width of the second opening OH2 in the second resin layers 21 and 22 is smaller than the opening width of the first opening OH1 in the first resin layer 12. That is, the second resin layers 21 and 22 including the second opening portion OH2 define the first opening portion OH1 and protrude into the hollow portion HP more than the side surface of the first resin layer 12 parallel to the stacking direction. The opening width of the second opening portion OH2 has a portion wider than the line width of the signal conductor pattern 4. That is, in the present example embodiment, the diameter of the second opening OH2 is larger than the line width of the signal conductor pattern 4.

Note that the present invention is not limited to the present example embodiment, and in the present invention, the “stacking direction” does not mean the direction of the stacking order of the layers at the time of manufacturing, but means the direction of stacking of the layers in the illustrated state.

As illustrated in FIG. 1, the high-frequency signal transmission line 101 includes six hollow portions HP, for example. That is, the signal conductor pattern 4 passes through the hollow portion HP at these six locations. The high-frequency signal transmission line 101 defines and functions as a strip line including the signal conductor pattern 4, the first ground conductor layer 51, the second ground conductor layer 52, the upper resin stacked portion 31, the lower resin stacked portion 32, and the hollow portion HP.

When the interval between the adjacent hollow portions HP is less than about ¼ wavelength of the transmission signal, the periodic change in the characteristic impedance accompanying the change in the relative permittivity around the signal conductor pattern 4 does not cause a problem.

As illustrated in FIG. 1, the signal conductor pattern terminal 4T separated from the first ground conductor layer 51 is on the upper surface of the upper resin stacked portion 31. An end of the signal conductor pattern 4 is connected to the signal conductor pattern terminal 4T via an interlayer connection conductor. A coaxial connector 61 is mounted on the upper signal conductor pattern terminal 4T, and a coaxial connector 62 is mounted on the lower signal conductor pattern terminal 4T. As described above, the high-frequency signal transmission line 101 is used as a transmission line having coaxial connectors at both ends. Regarding the coaxial connectors 61 and 62 in FIG. 1, mounting positions thereof are illustrated.

Each of the signal conductor pattern 4, the first ground conductor layer 51, and the second ground conductor layer 52 is, for example, a copper foil. The material of the first resin layers 11, 12, and 13 is, for example, polyimide, liquid crystal polymer, epoxy resin, or the like. The material of the second resin layers 21 and 22 includes, for example, thermoplastic polyimide, fluorine-based resin, polyolefin-based resin, or the like. The polyolefin-based resin includes, for example, styrene, polyethylene, polypropylene, or the like. The second resin layers 21 and 22 act as adhesive layers to bond adjacent first resin layers among the first resin layers 11, 12, and 13.

The flexibility of the second resin layers 21 and 22 at normal temperature is larger than the flexibility of the first resin layers 11, 12, and 13 at normal temperature. Here, the normal temperature is, for example, about 25 °C or room temperature.

For example, the Young's modulus of the second resin layers 21 and 22 is 1 MPa or less, and the Young's modulus of the first resin layers 11, 12, and 13 is about 2 MPa or more.

In addition, it is preferable that the second resin layers 21 and 22 have high fluidity at the processing stage. The second resin layers may flow, adhere a portion of the end surface (inner end surface) in the opening, and then cure. As a material of the second resin layers 21 and 22, for example, a prepreg material used for interlayer adhesion can be considered.

A relative permittivity of the second resin layer is lower than a relative permittivity of the first resin layer. For example, the relative permittivity of the second resin layers 21 and 22 is about 2.2 to about 2.8, and the relative permittivity of the first resin layers 11, 12, and 13 is about 2.8 to about 4.0.

A dielectric loss tangent of the second resin layer is lower than a dielectric loss tangent of the first resin layer. For example, the dielectric loss tangent of the second resin layers 21 and 22 is about 0.0005 to about 0.003, and the dielectric loss tangent of the first resin layers 11, 12, and 13 is about 0.002 to about 0.01.

Any one of the magnitude relationship of the relative permittivity and the magnitude relationship of the dielectric loss tangent may satisfy the above relationship.

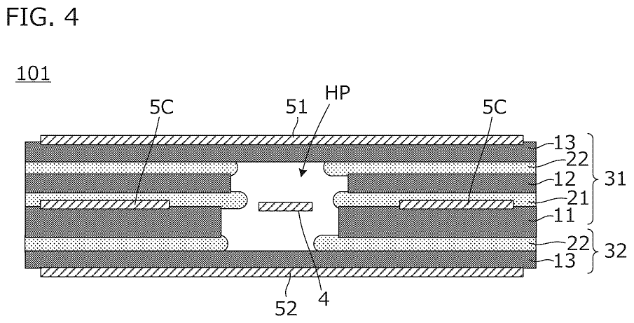

FIG. 4 is a cross-sectional view illustrating a stacking deviation state of each resin layer in the high-frequency signal transmission line of the present example embodiment. This cross-sectional position corresponds to the cross-sectional position of the cross-sectional view illustrated in the upper portion of FIG. 2.

As illustrated in FIG. 4, even if the stacking positions of the resin layers are shifted, the probability that a portion where the first resin layers 11 and 12 and the second resin layers 21, 22, and 22 do not overlap each other is generated is reduced.

According to the present example embodiment, even when there is stacking deviation between the second resin layers 21 and 22 as adhesive layers and the first resin layers 11, 12, and 13 as base material layers, a decrease in the adhesive area between the layers is reduced or prevented, and a decrease in the bonding strength between the layers can be prevented. As a result, the high-frequency signal transmission line 101 in which the strength of the resin stacked portion and the hollow portion is maintained high is obtained. In addition, the electrical characteristics of the high-frequency signal transmission line are stably maintained.

In addition, since the opening width of the second opening located in the second resin layer 21 in contact with the upper portion of the first resin layer 11 is greater than the line width of the signal conductor pattern 4, the signal conductor pattern 4 is hardly affected by the second resin layer 21.

Since the deviation of the stacking position of each resin layer is allowed by a predetermined amount, the high-frequency signal transmission line is easily processed.

In addition, since the second resin layers 21 and 22 have a low dielectric constant or a low dielectric loss tangent as compared with the first resin layers 11, 12, and 13, even if the protrusion amount of the second resin layers 21 and 22 with respect to the opening OH1 is large, the dielectric loss due to the second resin layer is small. In addition, the protrusion amount of the second resin layers 21 and 22 with respect to the opening OH1 is not always constant, but the change in the dielectric loss with respect to the change in the protrusion amount is small.

In the example illustrated in FIG. 1, the upper resin stacked portion 31 is configured by stacking three layers of the first resin layers 11, 12, and 13 and two layers of the second resin layers 21 and 22, and the lower resin stacked portion 32 is configured by stacking one layer of the lower first resin layer 13 and one layer of the lower second resin layer 22, but the number of the first resin layers and the number of the second resin layers are not limited thereto.

In the second example embodiment, a high-frequency signal transmission line in which the position of the opening of each resin layer defining the hollow portion HP is different from the example shown in the first example embodiment will be exemplified.

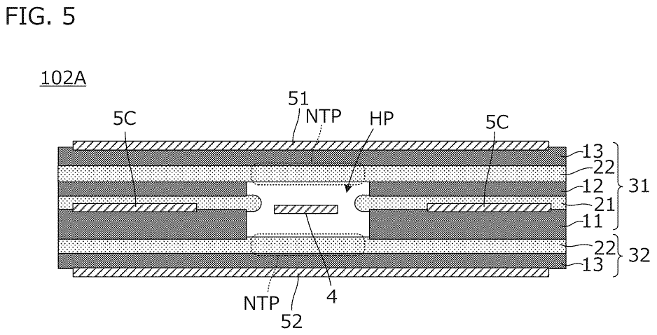

FIG. 5 is a cross-sectional view of a high-frequency signal transmission line 102A according to the second example embodiment. This cross-sectional position corresponds to the position illustrated in the upper portion of FIG. 2 in the first example embodiment.

A high-frequency signal transmission line 102A of the second example embodiment includes an upper resin stacked portion 31, a lower resin stacked portion 32, a signal conductor pattern 4, a first ground conductor layer 51, a second ground conductor layer 52, and a ground conductor pattern 5C. The ground conductor pattern 5C is electrically connected to the first ground conductor layer 51 and the second ground conductor layer 52 via the interlayer connection conductor (the interlayer connection conductor 5V described in the first example embodiment).

The circular first opening is located in the first resin layers 11 and 12, and the circular second opening is located in the second resin layer 21, so that the hollow portion HP is provided at these openings.

The opening width of the second opening located in the second resin layer 21 is smaller than the opening width of the first opening located in the first resin layers 11 and 12, and the opening width of the second opening is greater than the line width of the signal conductor pattern 4.

As illustrated in FIG. 5, a non-penetrating portion NTP is located in the upper and lower second resin layers 22. That is, the second resin layer 22 at the uppermost portion of the hollow portion HP does not have an opening continuous with the opening of the first resin layer 12. Similarly, the second resin layer 22 located at the lowermost portion of the hollow portion HP does not have an opening continuous with the opening of the first resin layer 11.

According to the present example embodiment, since the second resin layers 22 and 22 as the adhesive layers are disposed above and below the hollow portion HP, there is no decrease in the adhesive area due to the stacking deviation between the second resin layers 22 and 22 and the first resin layers 13 and 13 as the base material layers. That is, since the second resin layers 22 and 22 and the first resin layers 13 and 13 which are outer layers thereof are always adhered to each other in a wide area, a decrease in strength due to stacking deviation of the respective resin layers does not occur.

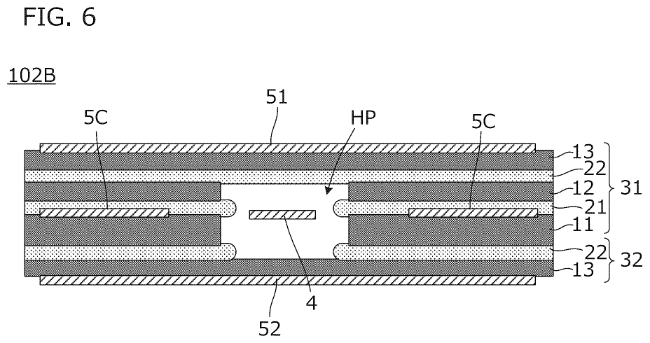

FIG. 6 is a cross-sectional view of another high-frequency signal transmission line 102B according to the second example embodiment. In the high-frequency signal transmission line 102A illustrated in FIG. 5, both the upper and lower layers of the hollow portion HP are the second resin layers 22 and 22, but in the high-frequency signal transmission line 102B illustrated in FIG. 6, the second resin layer 22 as an adhesive layer is disposed above the hollow portion HP, but the second resin layer 22 below the hollow portion HP includes an opening that is continuous with the opening of the first resin layer 11.

As described above, whether the opening is located in the second resin layer may be different between the upper portion and the lower portion of the hollow portion HP. As a result, the volume of the hollow portion HP can be secured, and a decrease in the bonding strength between the second resin layer and the first resin layer with respect to the stacking deviation between the second resin layer and the first resin layer can be reduced or prevented.

In the third example embodiment, a high-frequency signal transmission line in which the shape of the second resin layer by processing is different from that of the example embodiments described above will be exemplified.

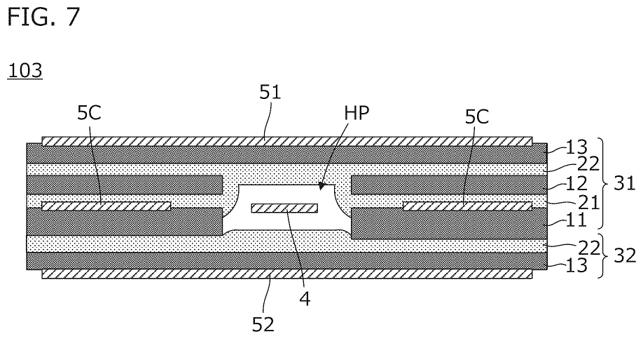

FIG. 7 is a cross-sectional view of a high-frequency signal transmission line 103 according to the third example embodiment.

The high-frequency signal transmission line 103 of the third example embodiment includes an upper resin stacked portion 31, a lower resin stacked portion 32, a signal conductor pattern 4, a first ground conductor layer 51, a second ground conductor layer 52, and a ground conductor pattern 5C. The ground conductor pattern 5C is electrically connected to the first ground conductor layer 51 and the second ground conductor layer 52 via the interlayer connection conductor (the interlayer connection conductor 5V described in the first example embodiment).

The circular first opening is located in the first resin layers 11 and 12, and the circular second opening is located in the second resin layer 21, so that the hollow portion HP is provided at these openings.

The opening width of the second opening located in the second resin layer 21 is smaller than the opening width of the first opening located in the first resin layers 11 and 12, and the opening width of the second opening is greater than the line width of the signal conductor pattern 4.

In the present example embodiment, as illustrated in FIG. 7, the second resin layer 21 protrudes into the openings of the first resin layers 11 and 12, so that the second resin layer 21 and the second resin layer 22 are continuous in the hollow portion HP.

According to the present example embodiment, since the second resin layer 21 and the upper second resin layer 22 as adhesive layers adhere to the entire end surface (inner surface) of the opening of the first resin layer 12 in the thickness direction, the adhesion strength between the second resin layers 21 and 22 and the first resin layer 12 is high. Therefore, the strength of the hollow portion HP is more effectively enhanced.

In the fourth example embodiment, a high-frequency signal transmission line in which the shape of the first resin layer supporting the signal conductor pattern is different from that of the example embodiment described above will be exemplified.

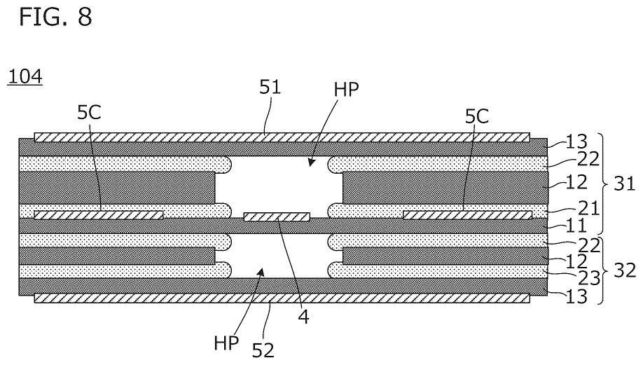

FIG. 8 is a cross-sectional view of a high-frequency signal transmission line 104 according to the fourth example embodiment.

The high-frequency signal transmission line 104 includes an upper resin stacked portion 31, a lower resin stacked portion 32, a signal conductor pattern 4, a first ground conductor layer 51, a second ground conductor layer 52, and a ground conductor pattern 5C.

The upper resin stacked portion 31 is a portion where the first resin layers 11, 12, and 13 and the second resin layers 21 and 22 are stacked. The lower resin stacked portion 32 is a portion where the first resin layers 12 and 13 and the second resin layers 22 and 23 are stacked.

The signal conductor pattern 4 and the ground conductor pattern 5C are on the upper surface of the first resin layer 11. A first ground conductor layer 51 is stacked on the upper surface of the upper first resin layer 13. A second ground conductor layer 52 is stacked on the lower surface of the lower first resin layer 13.

A circular opening is located in the upper first resin layer 12 and second resin layers 21 and 22. In addition, circular openings are located in the lower first resin layer 12 and the lower second resin layers 22 and 23.

Other structures are similar to those of the high-frequency signal transmission line described in the first example embodiment.

According to the present example embodiment, since the first resin layer 11 continuously supporting the signal conductor pattern 4 is present, the strength of the signal conductor pattern 4 can be easily increased.

In the fifth example embodiment, a high-frequency signal transmission line including a hollow portion HP only on one of the upper and lower sides of a signal conductor pattern will be exemplified.

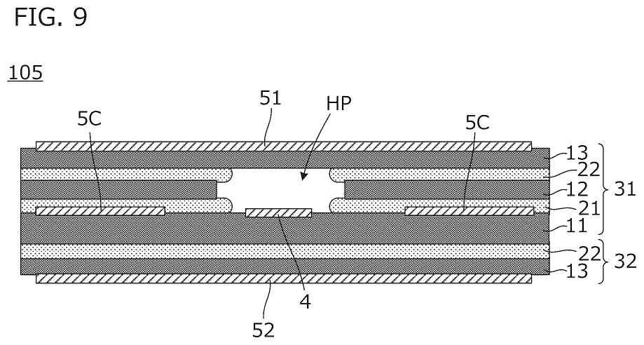

FIG. 9 is a cross-sectional view of a high-frequency signal transmission line 105 according to the fifth example embodiment.

The high-frequency signal transmission line 105 includes an upper resin stacked portion 31, a lower resin stacked portion 32, a signal conductor pattern 4, a first ground conductor layer 51, a second ground conductor layer 52, and a ground conductor pattern 5C.

The signal conductor pattern 4 and the ground conductor pattern 5C are on the upper surface of the first resin layer 11. A first ground conductor layer 51 is stacked on the upper surface of the upper first resin layer 13. A second ground conductor layer 52 is stacked on the lower surface of the lower first resin layer 13.

A circular opening is located in the upper first resin layer 12 and second resin layers 21 and 22. No opening is located in the lower first resin layer 13 and the lower second resin layer 22.

According to the present example embodiment, since there is no hollow portion on one of the upper and lower sides of the signal conductor pattern 4, it is possible to obtain a high-frequency signal transmission line having high strength in the hollow portion HP and high strength in the entire high-frequency signal transmission line 105.

In the sixth example embodiment, a high-frequency signal transmission line including a single ground conductor layer will be exemplified.

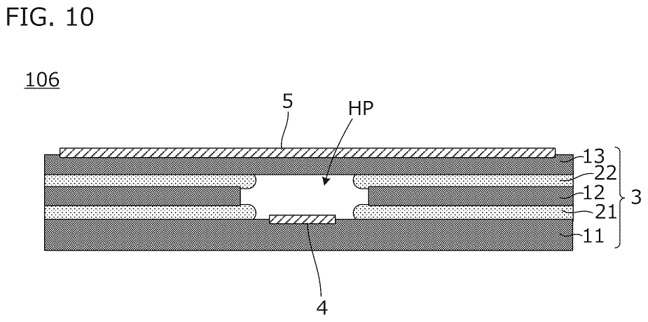

FIG. 10 is a longitudinal cross-sectional view of a high-frequency signal transmission line 106 according to the sixth example embodiment.

The high-frequency signal transmission line 106 includes a resin stacked portion 3, a signal conductor pattern 4, and a ground conductor layer 5.

The resin stacked portion 3 is a portion where first resin layers 11, 12, and 13 and second resin layers 21 and 22 are stacked. The signal conductor pattern 4 is on the upper surface of the first resin layer 11. The ground conductor layer 5 is stacked on the upper surface of the first resin layer 13. That is, the signal conductor pattern 4 and the ground conductor layer 5 face each other with a portion of the resin stacked portion 3 interposed therebetween.

A circular opening is located in the first resin layer 12 and the second resin layers 21 and 22. When expressed by the shape in the drawing, this opening is circular as viewed in the stacking direction of the first resin layers 11, 12, and 13 and the second resin layers 21 and 22.

The circular first opening is located in the first resin layer 12, and the circular second opening is located in the second resin layers 21 and 22, so that the hollow portion HP is provided at these openings.

The opening width of the second opening located in the second resin layers 21 and 22 is smaller than the opening width of the first opening located in the first resin layer 12, and the opening width of the second opening is greater than the line width of the signal conductor pattern 4.

As exemplified in the present example embodiment, the present invention can also be applied to a microstrip-line-type high-frequency signal transmission line.

In the seventh example embodiment, another high-frequency signal transmission line including a single ground conductor layer is illustrated.

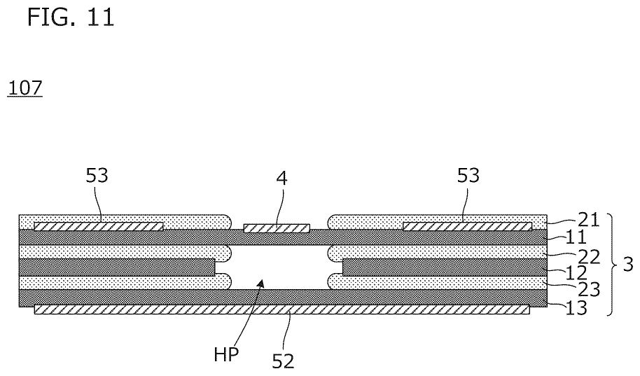

FIG. 11 is a longitudinal cross-sectional view of a high-frequency signal transmission line 107 according to the seventh example embodiment.

The high-frequency signal transmission line 107 includes a resin stacked portion 3, a signal conductor pattern 4, and ground conductor layers 52 and 53.

The resin stacked portion 3 is a portion where the first resin layers 11, 12, and 13 and the second resin layers 21, 22, and 23 are stacked. The signal conductor pattern 4 is on the upper surface of the first resin layer 11. On the upper surface of the first resin layer 11, a third ground conductor layer 53 is formed along the signal conductor pattern 4. A second ground conductor layer 52 is stacked on the lower surface of the first resin layer 13. That is, the signal conductor pattern 4 and the second ground conductor layer 52 face each other with a portion of the resin stacked portion 3 interposed therebetween, and the third ground conductor layers 53 are disposed on both side portions of the signal conductor pattern 4.

The circular first opening is located in the first resin layer 12, and the circular second opening is located in the second resin layers 22 and 23, so that the hollow portion HP is provided at these openings.

The opening width of the second opening located in the second resin layers 22 and 23 is smaller than the opening width of the first opening located in the first resin layer 12, and the opening width of the second opening is greater than the line width of the signal conductor pattern 4.

Example embodiments of the present invention can also be applied to a high-frequency signal transmission line of a type as exemplified in the present example embodiment.

In the eighth example embodiment, a high-frequency signal transmission line in which the positional relationship between the hollow portion and the interlayer connection conductor and the structure of the interlayer connection conductor are different from those of the examples described above will be exemplified.

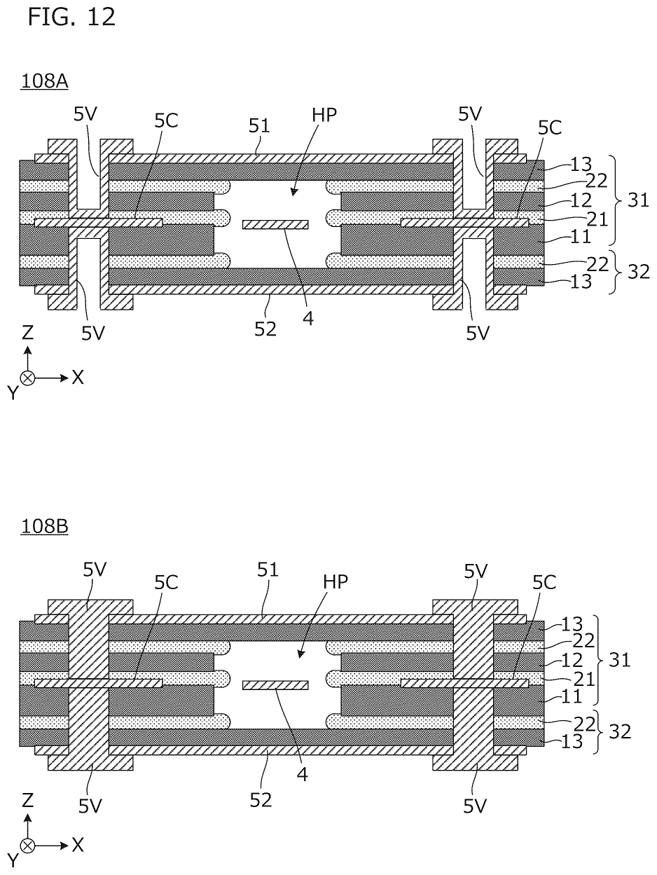

The upper portion of FIG. 12 is a cross-sectional view of a high-frequency signal transmission line 108A according to the eighth example embodiment. This example is a cross-sectional view at a position passing through the two interlayer connection conductors 5V sandwiching the hollow portion HP and the hollow portion HP. The high-frequency signal transmission line 108A includes an upper resin stacked portion 31, a lower resin stacked portion 32, a signal conductor pattern 4, a first ground conductor layer 51, a second ground conductor layer 52, a ground conductor pattern 5C, and an interlayer connection conductor 5V.

The interlayer connection conductor 5V is formed by forming a hole to expose the ground conductor pattern 5C from the outer surface of the stacked body obtained by stacking the resin layers by laser processing, and forming a copper plated film in the hole.

The lower portion of FIG. 12 is a cross-sectional view of a high-frequency signal transmission line 108B according to the eighth example embodiment. This example is also a cross-sectional view at a position passing through the two interlayer connection conductors 5V sandwiching the hollow portion HP and the hollow portion HP. In the high-frequency signal transmission line 108B, the opening located in each resin layer between the first ground conductor layer 51 and the ground conductor pattern 5C of the high-frequency signal transmission line 107A is filled with a conductor to form the interlayer connection conductor 5V, and the opening located in each resin layer between the second ground conductor layer 52 and the ground conductor pattern 5C is filled with a conductor to form the interlayer connection conductor 5V.

In the ninth example embodiment, a high-frequency signal transmission line including a protective film on an outer surface will be exemplified.

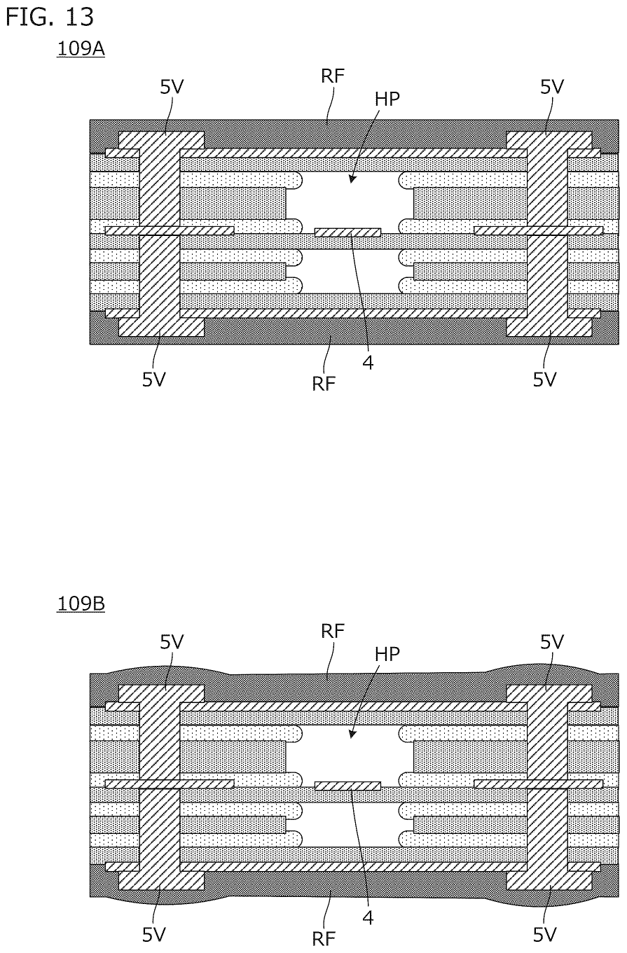

The upper portion of FIG. 13 is a longitudinal cross-sectional view of a high-frequency signal transmission line 109A according to the ninth example embodiment. The high-frequency signal transmission line 109A is a high-frequency signal transmission line formed by forming a resist film on the high-frequency signal transmission line 104 illustrated in FIG. 8.

The lower portion of FIG. 13 is a longitudinal cross-sectional view of a high-frequency signal transmission line 109B according to the ninth example embodiment. The high-frequency signal transmission line 109B shows a longitudinal cross-sectional view of the high-frequency signal transmission line 109B configured by forming a resist film on the high-frequency signal transmission line 104 illustrated in FIG. 8.

The resist film RF illustrated in FIG. 13 is a resist film obtained by applying a resist resin to the front and back surfaces of the high-frequency signal transmission line 104 illustrated in FIG. 8 and then curing the resist resin.

In this way, by providing the resist film RF on the outer surface, the stress applied to the high-frequency signal transmission lines 109A and 109B from the outside is relaxed by the resist film RF, and a decrease in the strength of the high-frequency signal transmission line due to the presence of the hollow portion HP is reduced or prevented.

In particular, in the high-frequency signal transmission line 109B, even if some object abuts from the outside, the stress received by the resist film RF is concentrated on the interlayer connection conductor 5V, so that the hollow portion HP is effectively protected.

In the tenth example embodiment, a high-frequency signal transmission line in which the positional relationship between the hollow portion and the interlayer connection conductor is different from those of the examples described above will be exemplified.

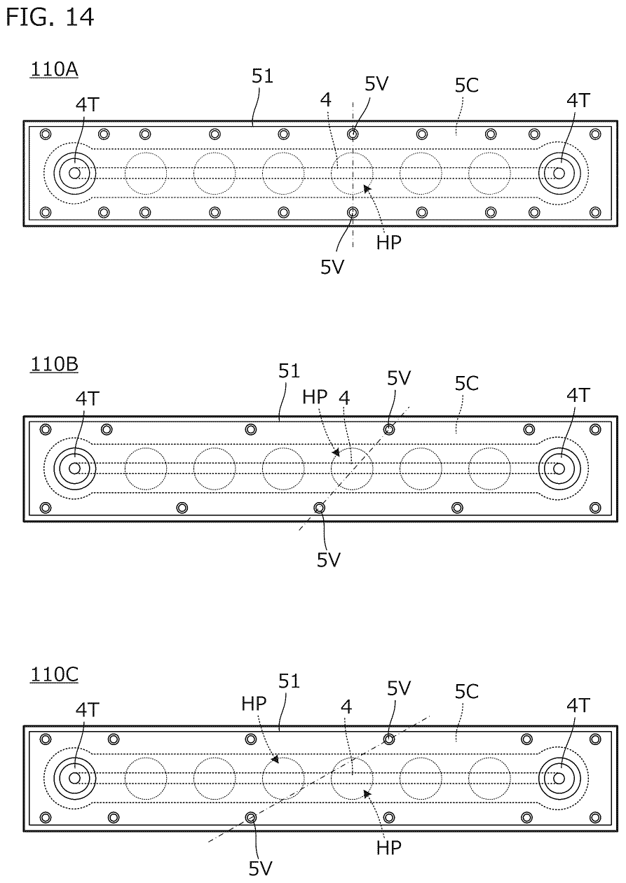

FIG. 14 is a plan view of high-frequency signal transmission lines 110A, 110B, and 110C according to the tenth example embodiment. Each of the high-frequency signal transmission lines 110A, 110B, and 110C includes a first ground conductor layer 51, a ground conductor pattern 51C, a signal conductor pattern terminal 4T, a plurality of hollow portions HP, and a plurality of interlayer connection conductors 5V. The inner structure is as shown in the first example embodiment and the like. The second ground conductor layer 52 overlaps with the first ground conductor layer 51 in the plan view. Since the interlayer connection conductors 5V adjacent to the hollow portion HP are located at positions across the hollow portion HP as viewed in the stacking direction of the resin layers, the interlayer connection conductors 5V are located at positions adjacent to the hollow portion HP.

The high-frequency signal transmission lines 110A, 110B, and 110C are different from each other in the arrangement of the interlayer connection conductors 5V. In both the high-frequency signal transmission lines 110B and 110C, the number of interlayer connection conductors is smaller than that in the example illustrated in FIG. 1. In the high-frequency signal transmission line 110A, the interlayer connection conductors 5V are arranged on both sides of the hollow portion HP as viewed in the stacking direction of the respective resins. In the high-frequency signal transmission line 110A, since the interlayer connection conductor 5V exists at a position close to each of the hollow portions HP, the strength of the hollow portion HP is effectively enhanced by the interlayer connection conductor 5V.

In the eleventh example embodiment, a high-frequency signal transmission line in which upper and lower portions of a stacked resin body are recessed will be exemplified.

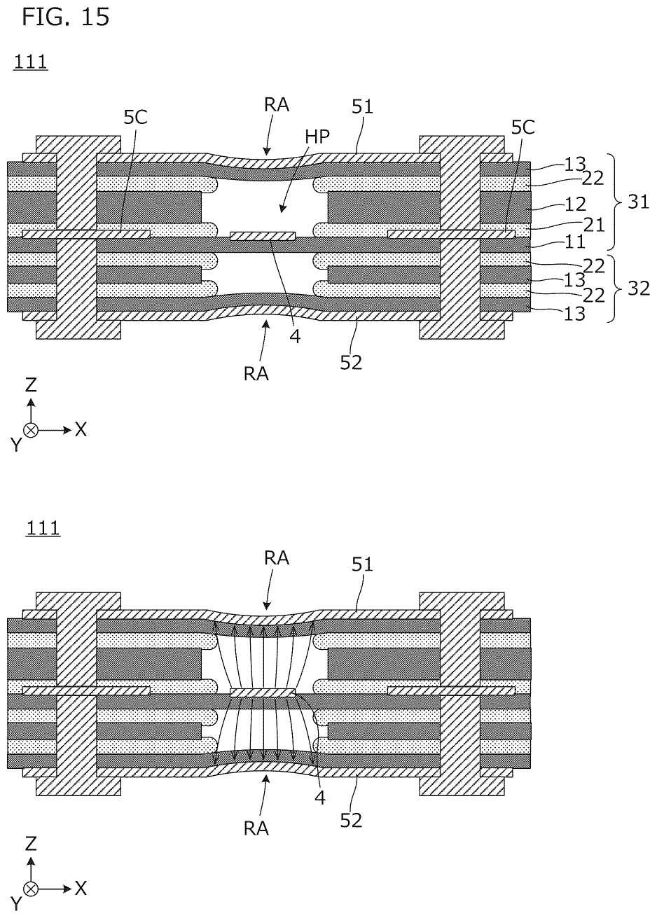

The upper portion of FIG. 15 is a cross-sectional view of a high-frequency signal transmission line 111 according to the eleventh example embodiment. The lower portion of FIG. 15 is a cross-sectional view of the high-frequency signal transmission line 111 illustrating a state of the electric field distribution by the lines of electric force. The high-frequency signal transmission line 111 includes an upper resin stacked portion 31, a lower resin stacked portion 32, a signal conductor pattern 4, a first ground conductor layer 51, a second ground conductor layer 52, and a ground conductor pattern 5C. The other basic structures are similar to those of the high-frequency signal transmission line 104 illustrated in FIG. 8.

The lower portion of FIG. 15 is a cross-sectional view of the high-frequency signal transmission line 111 according to the present example embodiment, and is a cross-sectional view of the same portion as the upper portion of FIG. 15. An arrow drawn so as to jump out from the signal conductor pattern 4 in the lower portion of FIG. 15 is a notable line of electric force. As described above, an electric field is generated between the signal conductor pattern 4 and the first ground conductor layer 51 and between the signal conductor pattern 4 and the second ground conductor layer 52. As illustrated in this drawing, the closer to both ends of the signal conductor pattern 4, that is, the farther from the center of the signal conductor pattern 4, the longer the lines of electric force from the signal conductor pattern 4 to the first ground conductor layer 51 and the second ground conductor layer 52 become.

In the signal conductor pattern 4, the current density increases toward both ends thereof due to the edge effect (skin effect) of conductors. However, according to the above configuration, the electric field intensity is reduced or prevented toward both ends of the signal conductor pattern 4, so that the current distribution in the signal conductor pattern 4 is averaged. As a result, the conductor loss due to the signal conductor pattern 4 is relaxed.

In the twelfth example embodiment, a high-frequency signal transmission line in which the structures of the upper and lower outer surfaces of the hollow portion are different from those of the examples described above will be exemplified.

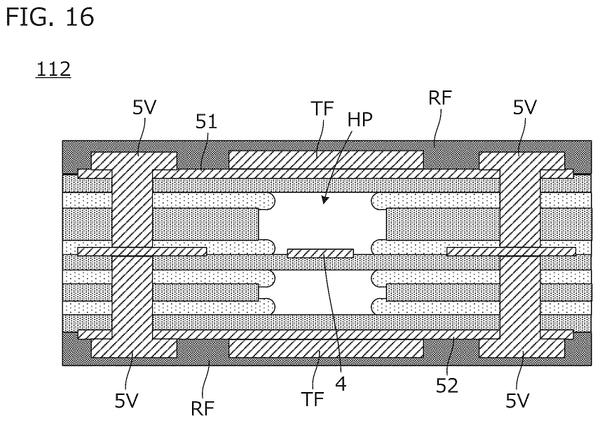

FIG. 16 is a longitudinal cross-sectional view of a high-frequency signal transmission line 112 according to the twelfth example embodiment. In this example, a thickened portion TF is formed by increasing the plating thickness of the region overlapping the hollow portion HP in the first ground conductor layer 51 and the second ground conductor layer 52 as viewed in the stacking direction of the layers. Plating in this region may be performed simultaneously with plating for forming the interlayer connection conductor 5V.

According to the present example embodiment, the strength of the upper and lower portions of the hollow portion HP in the stacked body is effectively enhanced. As a result, deformation of the hollow portion HP can be more effectively reduced or prevented.

An example of an electronic device will be described in the thirteenth example embodiment.

The high-frequency signal transmission line according to an example embodiment of the present invention can be used as a high-frequency signal transmission line in various electronic devices. For example, connectors are provided in the respective high-frequency circuits on the two circuit boards, and for example, the coaxial connectors 61 and 62 of the high-frequency signal transmission line 101 illustrated in FIG. 1 are connected. The circuit board and the high-frequency signal transmission line 101 are housed in a housing having a predetermined shape. The electronic device is configured in this manner.

Finally, the present invention is not limited to each example embodiment described above. Modifications and alterations can be appropriately made by those skilled in the art. The scope of the present invention is defined not by the above-described example embodiments but by the claims. Further, the scope of the present invention includes modifications and alterations from the example embodiments within the scope equivalent to the claims.

For example, in each example embodiment described above, an example in which both the first resin layer and the second resin layer include a plurality of layers is provided, but the first resin layer or the second resin layer may be single.

In each example embodiment, the high-frequency signal transmission line including a single signal conductor pattern is shown, but a plurality of signal conductor patterns may be provided. The plurality of signal conductor patterns may be arranged in the layer direction of each resin layer, or may be arranged in the stacking direction of the resin layers.

In addition, in each example embodiment, the rectangular high-frequency signal transmission line is illustrated as viewed from the stacking direction of the resin layers, but this shape is arbitrary.

In each example embodiment, the high-frequency signal transmission line including the linear signal conductor pattern is illustrated, but the signal conductor pattern may be curved or partially curved as viewed from the stacking direction of the resin layers.

In each example embodiment, the high-frequency signal transmission line having a planar shape is illustrated, but the stacked surface of each resin layer may be, for example, a curved surface such as a cylindrical surface or a partially curved surface. Further, for example, a portion or an entirety may be a torsional curved surface.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A high-frequency signal transmission line comprising:
a resin stacked portion in which a single or a plurality of first resin layers and a single or a plurality of second resin layers are stacked, a signal conductor pattern in contact with at least a single first resin layer of the first resin layers, and a ground conductor layer in contact with at least a single first resin layer of the first resin layers; wherein
a first opening is located in at least a single first resin layer among the first resin layers at a position along the signal conductor pattern in the resin stacked portion, and a second opening overlapping the first opening is located in at least a single second resin layer among the second resin layers, so that a hollow portion is provided in the resin stacked portion at the first opening or the second opening;
an opening width of the second opening is smaller than an opening width of the first opening;
an opening width of the second opening is greater than a line width of the signal conductor pattern; and
the second resin layer has a lower dielectric constant or a lower dielectric loss tangent than the first resin layer.

2. The high-frequency signal transmission line according to claim 1, wherein the ground conductor layer includes at least two ground conductor layers facing the signal conductor pattern with a portion or an entirety of the resin stacked portion interposed therebetween.

3. The high-frequency signal transmission line according to claim 1, wherein the second resin layers at an uppermost portion and a lowermost portion of the hollow portion include the second opening continuous with the first opening of the first resin layer.

4. The high-frequency signal transmission line according to claim 1, wherein the second resin layers at an uppermost portion and a lowermost portion of the hollow portion do not have an opening continuous with the first opening of the first resin layer.

5. The high-frequency signal transmission line according to claim 1, wherein the signal conductor pattern includes a portion that is not in contact with the first resin layer and the second resin layer in a direction orthogonal to a direction of the stacking in the second opening.

6. The high-frequency signal transmission line according to claim 1, further comprising:
an interlayer connection conductor in the resin stacked portion and electrically connected to the ground conductor layer; wherein
the interlayer connection conductor includes a protruding portion protruding from the ground conductor layer to an outside of the resin stacked portion.

7. The high-frequency signal transmission line according to claim 6, further comprising:
a third resin layer covering the protruding portion, on an outer surface of the resin stacked portion.

8. The high-frequency signal transmission line according to claim 1, wherein a vicinity of the hollow portion in the resin stacked portion is recessed in a direction of the stacking as compared with a portion located a predetermined distance away.

9. The high-frequency signal transmission line according to claim 1, wherein the first resin layer includes a polyimide, a liquid crystal polymer, or an epoxy resin, and the second resin layer includes a thermoplastic polyimide, a fluorine-based resin, or a polyolefin-based resin.

10. The high-frequency signal transmission line according to claim 1, wherein the resin stacked portion is configured in a first stacking direction and a second stacking direction opposite to the first stacking direction with respect to the signal conductor pattern.

11. The high-frequency signal transmission line according to claim 1, wherein the hollow portion overlaps with the signal conductor pattern when viewed in a direction of the stacking, and is located between the signal conductor pattern and the ground conductor layer.

12. The high-frequency signal transmission line according to claim 1, wherein the second resin layer including the second opening portion protrudes into the hollow portion beyond a side surface of the first resin layer, the side surface defining the first opening portion and being parallel to a direction of the stacking.

13. The high-frequency signal transmission line according to claim 1, wherein the high-frequency signal transmission line is a strip-line high-frequency signal transmission line.

14. The high-frequency signal transmission line according to claim 1, further comprising additional hollow portions in the resin stacked portion at the first opening or the second opening.

15. The high-frequency signal transmission line according to claim 14, wherein a total number of the hollow portions is six.

16. The high-frequency signal transmission line according to claim 14, wherein an interval between adjacent pairs of the hollow portions is about ¼ wavelength of a transmission signal transmitted by the high-frequency signal transmission line.

17. The high-frequency signal transmission line according to claim 1, wherein the second resin layer has a lower Young's modulus than that of the first resin layer.

18. The high-frequency signal transmission line according to claim 1, wherein a stacked surface of each resin layer is a curved surface, a cylindrical surface, a partially curved surface, or a torsional curved surface.

19. The high-frequency signal transmission line according to claim 1, wherein the signal conductor pattern is linear, curved, partially curved or has a planar shape.

20. An electronic device comprising the high-frequency signal transmission line according to claim 1.
